(19) United States
(12) Patent Application Publication
(10) Pub. No.: US 2025/0280620 A1
(43) Pub. Date: Sep. 4, 2025

(54) IMAGE SENSOR

(71) Applicant: Taiwan Semiconductor Manufacturing Company, Ltd., Hsinchu (TW)

(72) Inventors: Keng-Yu Chou, Kaohsiung City (TW); Chun-Hao Chuang, Hsinchu City (TW); Wei-Chieh Chiang, Changhua County (TW); Tzu-Jui Wang, Kaohsiung City (TW); Wen-Hau Wu, New Taipei City (TW); Cheng-Yu Huang, Hsinchu (TW); Yi-Hsuan Wang, Hsinchu City (TW)

(73) Assignee: Taiwan Semiconductor Manufacturing Company, Ltd., Hsinchu (TW)

(21) Appl. No.: 18/592,485

(22) Filed: Feb. 29, 2024

(51) Int. Cl. H01L 27/146; H04N 25/77; H04N 25/79

(52) U.S. Cl. CPC H10F 39/809; H04N 25/77; H04N 25/79; H10F 39/802; H10F 39/811; H10F 39/813

(57) ABSTRACT

An image sensor includes a sensing unit. The sensing unit includes a plurality of pixels. Each of the plurality of pixels includes at least one photodiode, at least one first transistor and a first source follower transistor. The sensing unit further includes a plurality of second transistors and a second source follower transistor. In each of the plurality of pixels, the at least one photodiode is electrically connected to the first source follower transistor at least through the at least one first transistor, and electrically connected to the second source follower transistor at least through at least one corresponding second transistor among the plurality of second transistors.

### BACKGROUND

Integrated circuits (IC) with image sensors are used in a wide range of modern-day electronic devices. In recent years, complementary metal-oxide semiconductor (CMOS) image sensors (CISs) have begun to see widespread use, largely replacing charge-coupled devices (CCD) image sensors. Compared to CCD image sensors, CISs are increasingly favored due to low power consumption, a small size, fast data processing, a direct output of data, and low manufacturing cost.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 and FIG. 2 are respectively circuit diagrams of a sensing unit in an image sensor under a single output mode and a binning output mode according to some embodiments of the present disclosure.

FIG. 3 is a schematic exploded diagram of the sensing unit in FIG. 1 and FIG. 2.

FIG. 4 is a schematic partial sectional view of the sensing unit in FIG. 3.

FIG. 5 and FIG. 6 respectively circuit diagrams of a sensing unit in an image sensor under the single output mode and the binning output mode according to some embodiments of the present disclosure.

FIG. 7 is a schematic top view of the sensing unit in FIG. 5 and FIG. 6.

FIG. 8 and FIG. 9 respectively circuit diagrams of a sensing unit in an image sensor under the single output mode and the binning output mode according to some embodiments of the present disclosure.

FIG. 10 is a schematic top view of the sensing unit in FIG. 8 and FIG. 9.

FIG. 11 and FIG. 12 respectively circuit diagrams of a sensing unit in an image sensor under the single output mode and the binning output mode according to some embodiments of the present disclosure.

FIG. 13 is a schematic top view of the sensing unit in FIG. 11 and FIG. 12.

FIG. 14 and FIG. 15 respectively circuit diagrams of a sensing unit in an image sensor under the single output mode and the binning output mode according to some embodiments of the present disclosure.

FIG. 16 is a schematic top view of the sensing unit in FIG. 14 and FIG. 15.

FIG. 17 and FIG. 18 respectively circuit diagrams of a sensing unit in an image sensor under the single output mode and the binning output mode according to some embodiments of the present disclosure.

FIG. 19 is a schematic top view of the sensing unit in FIG. 17 and FIG. 18.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Many electronic devices (e.g., cameras, cellular telephones, computers, etc.) include an image sensor (e.g., an image sensor integrated chip (IC)) for capturing images. The modern-day image sensors are designed to include more than one photodiode (e.g., dual photodiodes or quad photodiodes) in each pixel for more functions, such as phase detection autofocus (PDAF), high dynamic range (HDR), single pixel output for high resolution and binning pixel output for low light condition. As pixel size shrinks below 2 μm, the device layout area adopts a shared pixel circuit design for enough layout. However, the shared design not only has complicated metal routing, but also has long floating node routing and large parasitic capacitance, resulting in low conversion gain and high read noise.

In the present disclosure, the single output mode and the binning output mode are executed by two pixel circuits, so the metal routings corresponding to different modes can be reduced separately. In addition, the multiple transistors of the two pixel circuits are disposed on different levels, for example, the multiple transistors of the two pixel circuits are disposed on different wafers and then electrically connected through conductors in the interconnect structures respectively on the wafers, so as to reduce the floating node routing and/or to reduce the parasitic capacitance caused by adjacent conductors on the same layer or different layers, which helps to improve conversion gain, lower the read noise and/or improve the image quality.

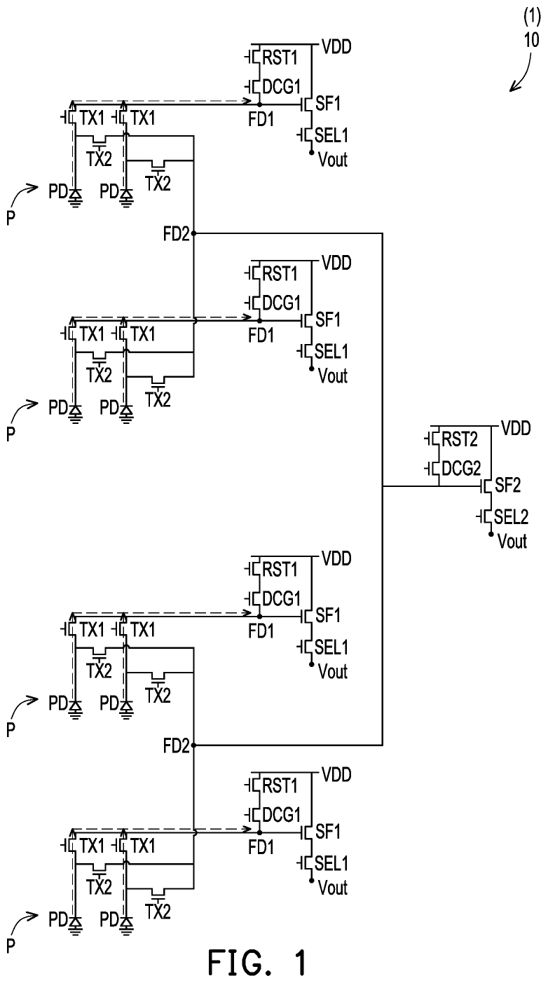

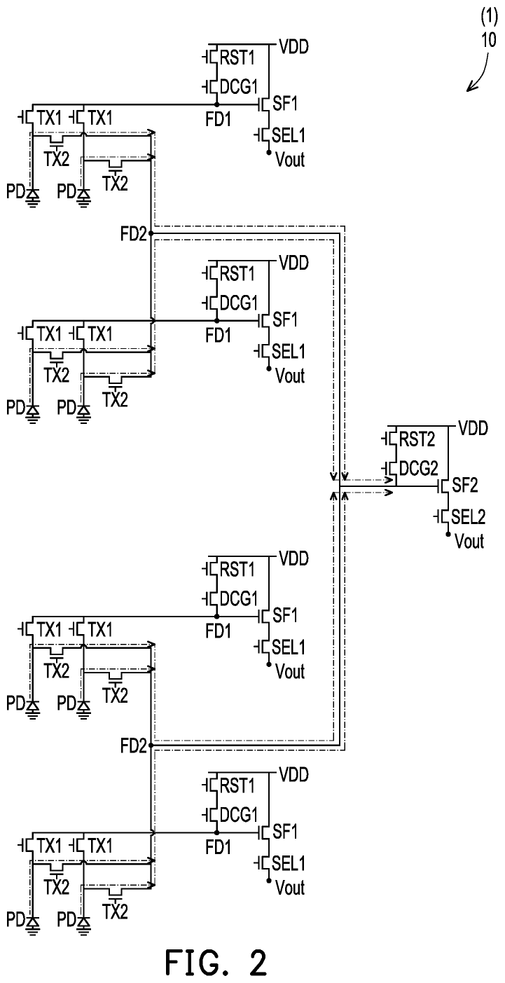

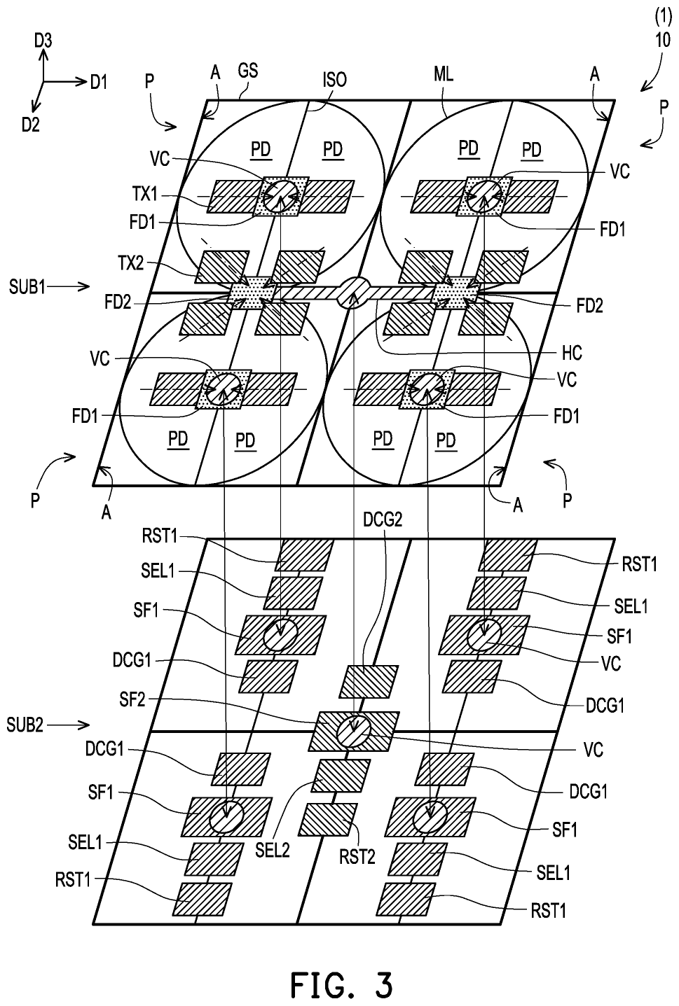

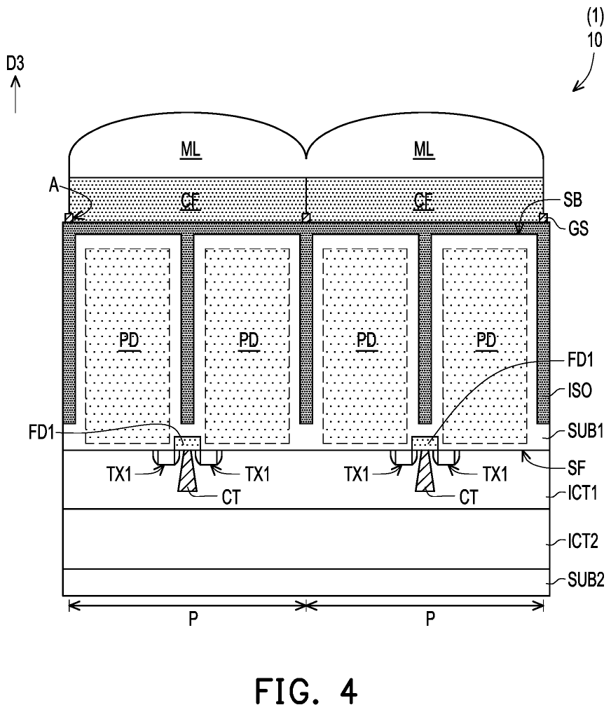

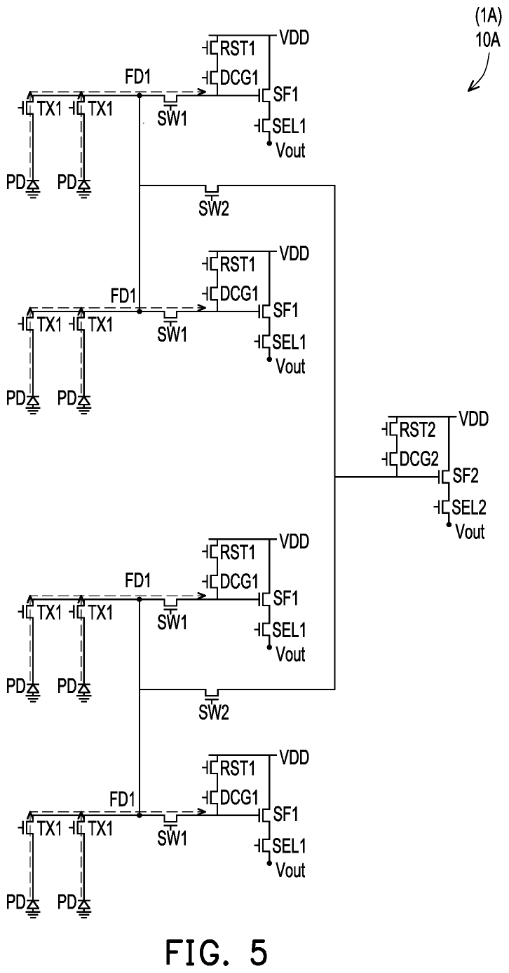

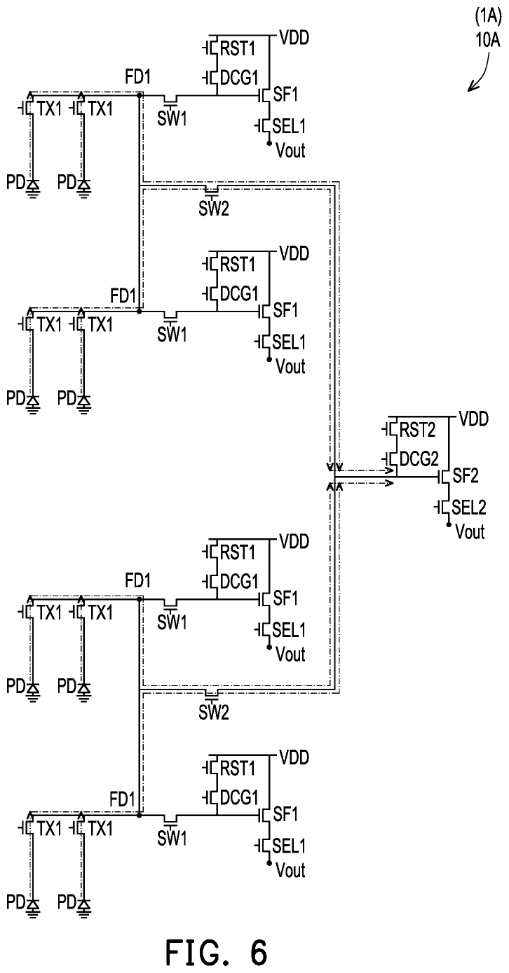

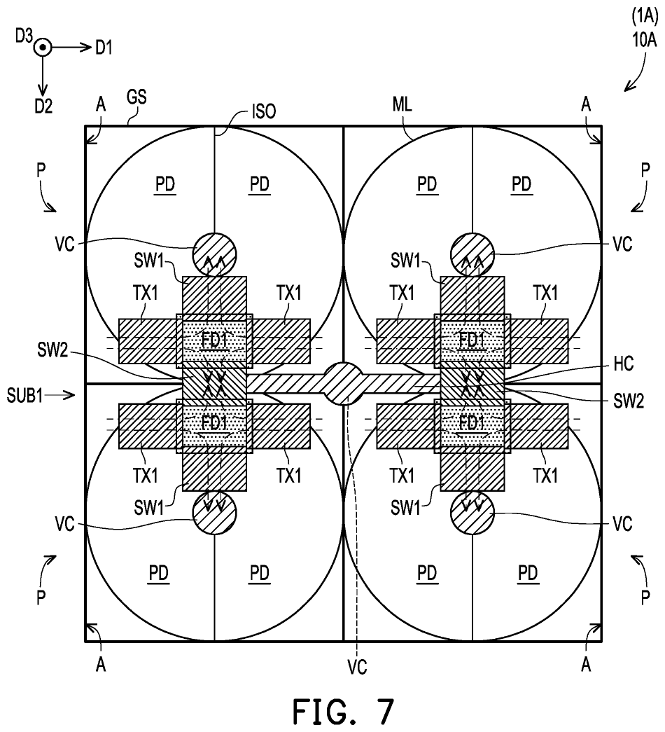

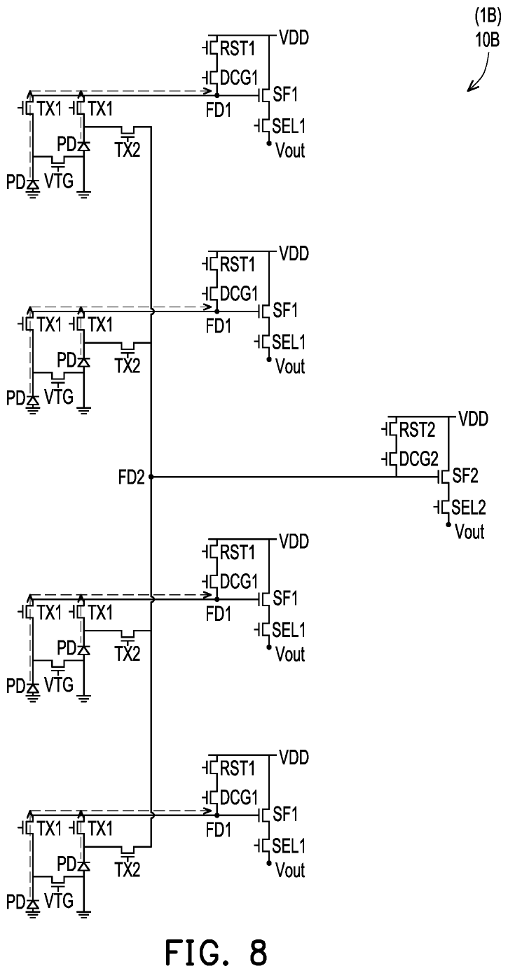

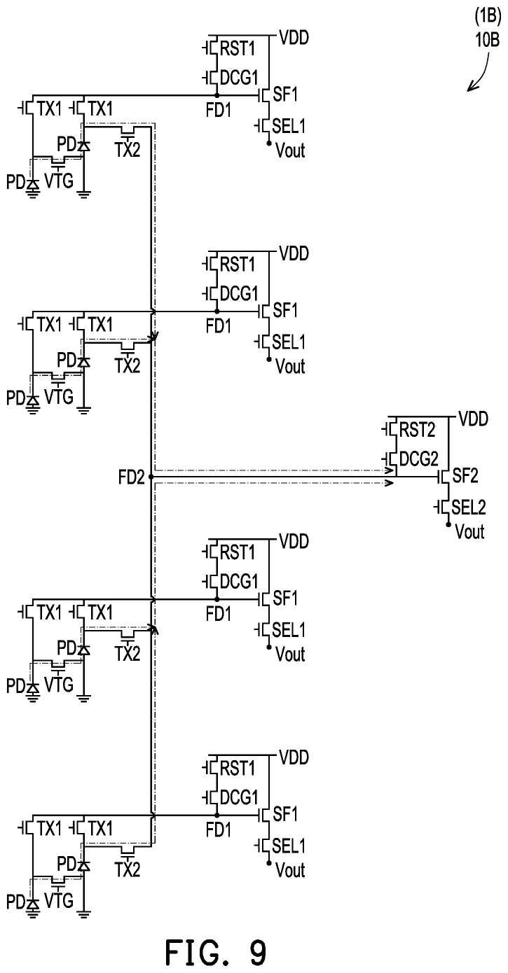

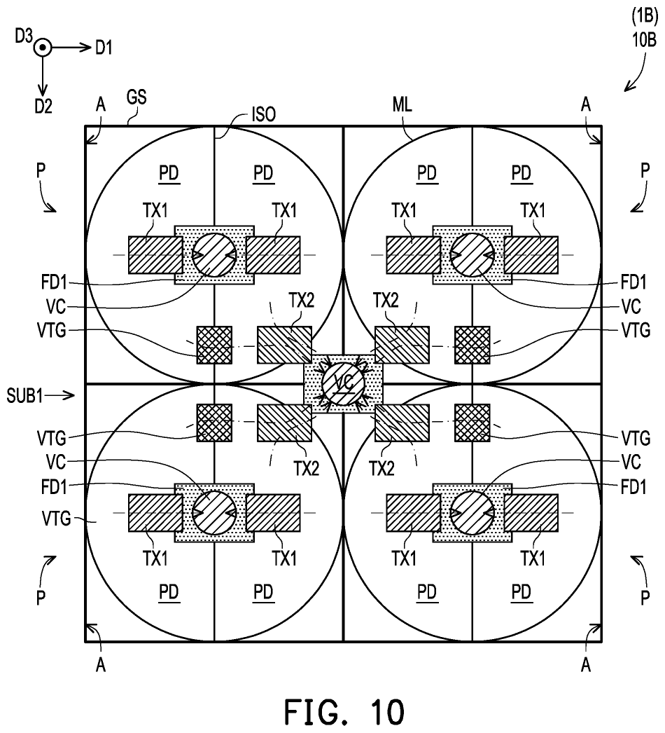

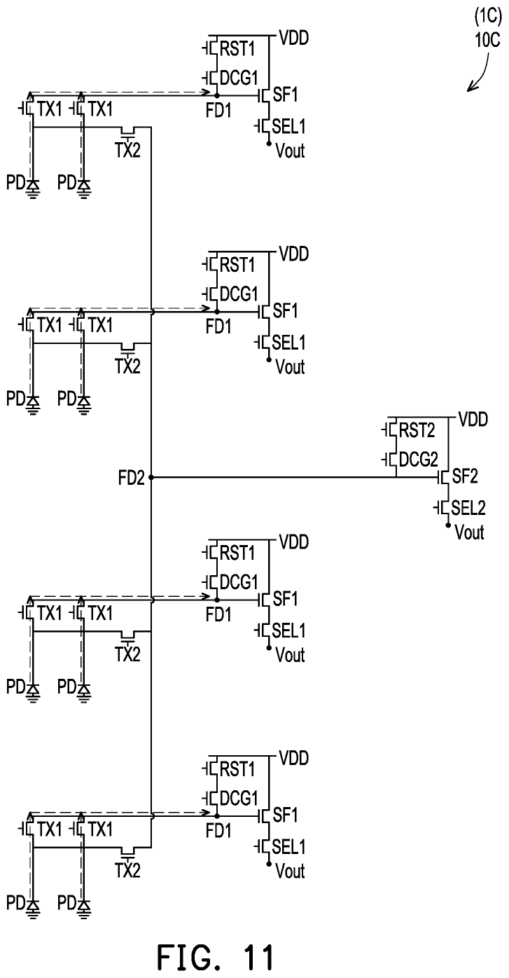

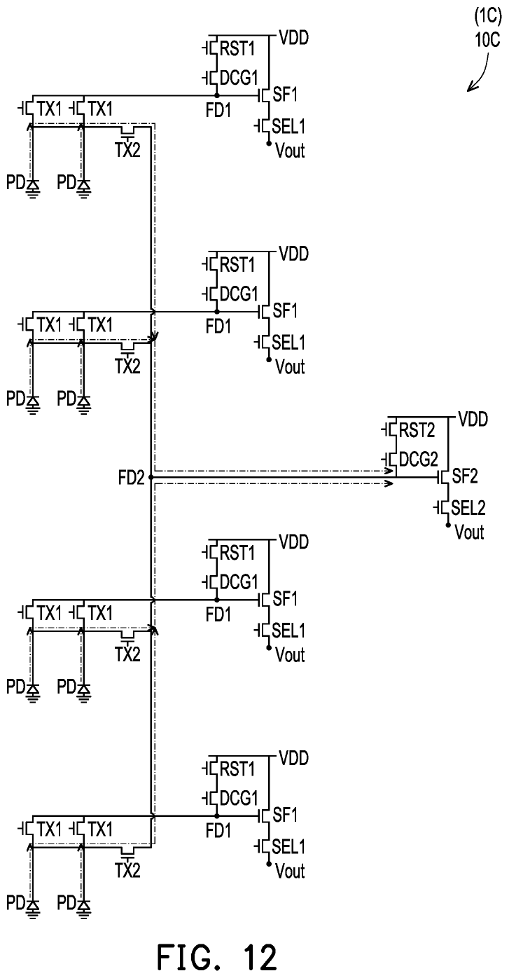

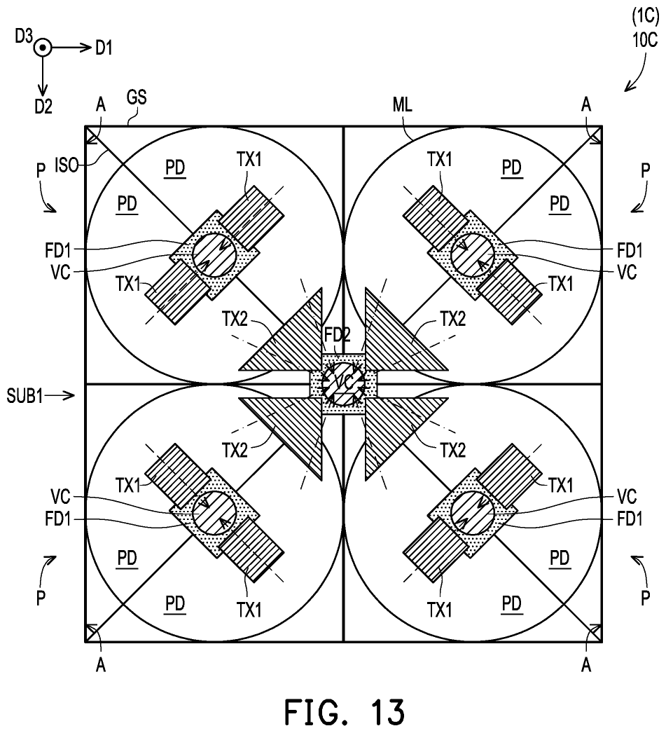

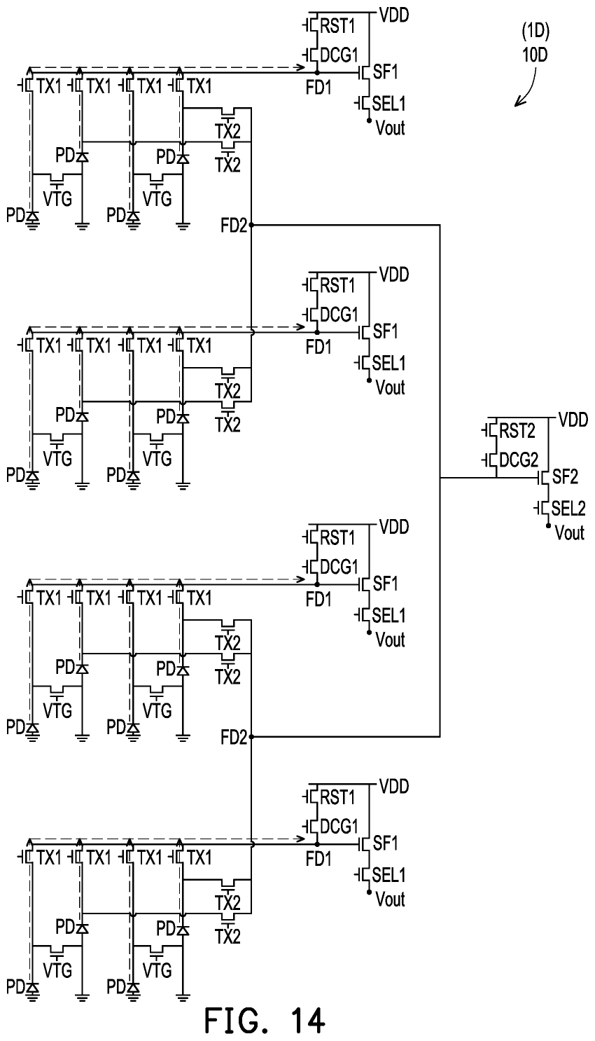

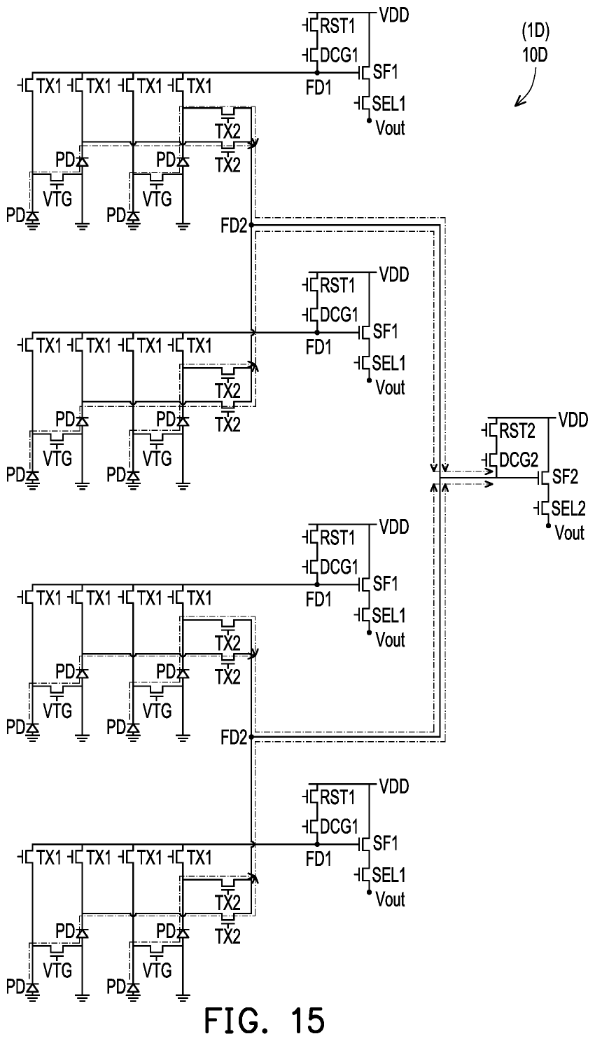

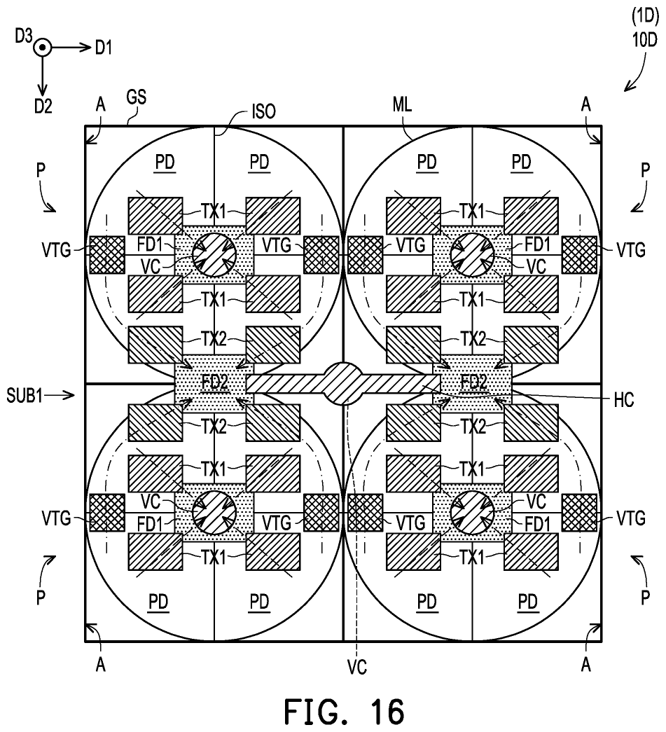

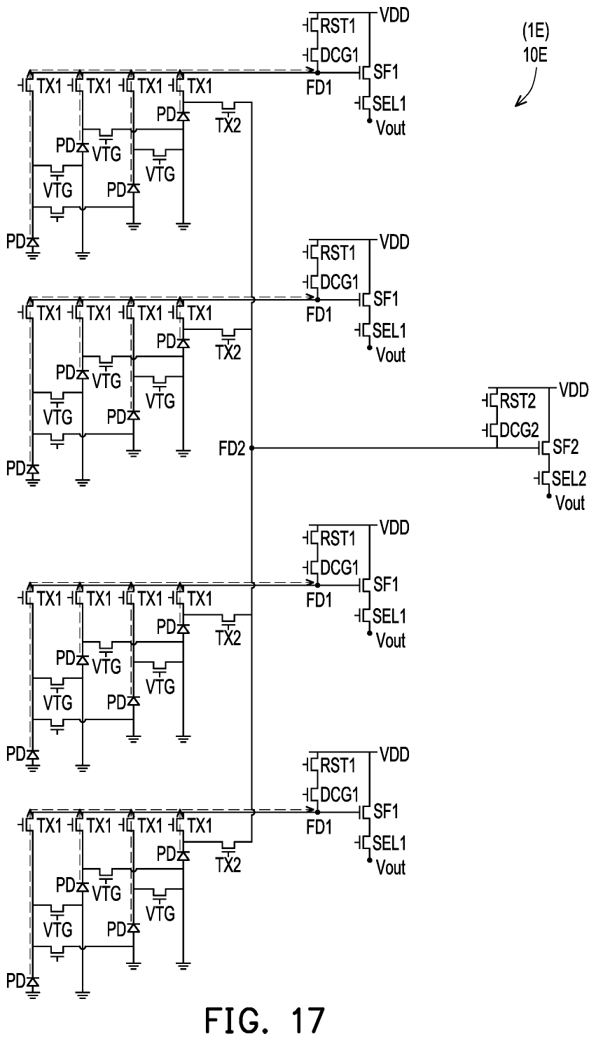

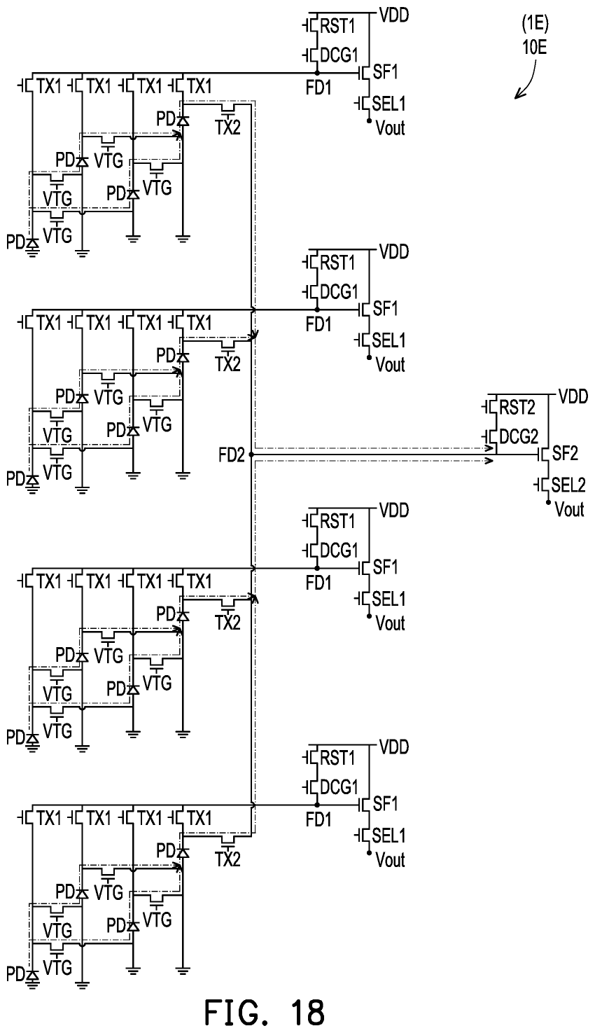

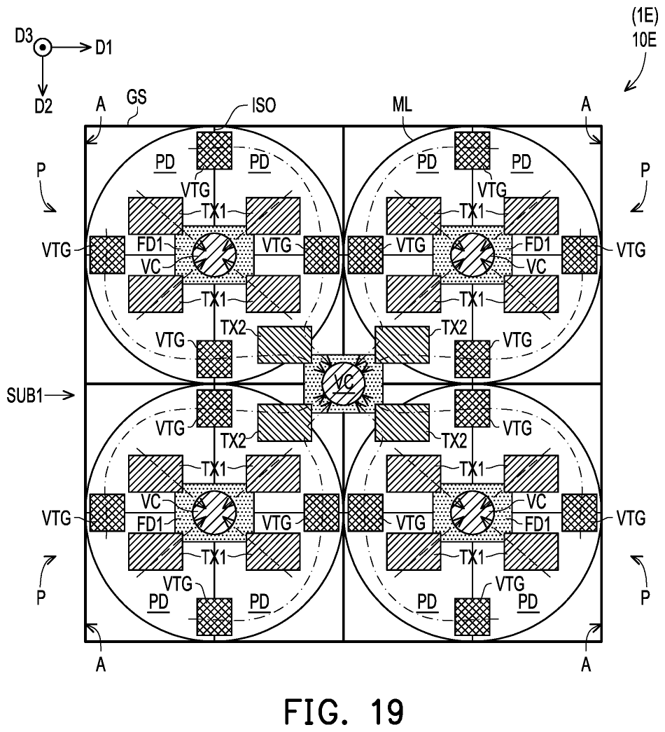

FIG. 1 and FIG. 2 are respectively circuit diagrams of a sensing unit in an image sensor under a single output mode and a binning output mode according to some embodiments of the present disclosure. FIG. 3 is a schematic exploded diagram of the sensing unit in FIG. 1 and FIG. 2. FIG. 4 is a schematic partial sectional view of the sensing unit in FIG. 3. FIG. 5 and FIG. 6 respectively circuit diagrams of a sensing unit in an image sensor under the single output mode and the binning output mode according to some embodiments of the present disclosure. FIG. 7 is a schematic top view of the sensing unit in FIG. 5 and FIG. 6. FIG. 8 and FIG. 9 respectively circuit diagrams of a sensing unit in an image sensor under the single output mode and the binning output mode according to some embodiments of the present disclosure. FIG. 10 is a schematic top view of the sensing unit in FIG. 8 and FIG. 9. FIG. 11 and FIG. 12 respectively circuit diagrams of a sensing unit in an image sensor under the single output mode and the binning output mode according to some embodiments of the present disclosure. FIG. 13 is a schematic top view of the sensing unit in FIG. 11 and FIG. 12. FIG. 14 and FIG. 15 respectively circuit diagrams of a sensing unit in an image sensor under the single output mode and the binning output mode according to some embodiments of the present disclosure. FIG. 16 is a schematic top view of the sensing unit in FIG. 14 and FIG. 15. FIG. 17 and FIG. 18 respectively circuit diagrams of a sensing unit in an image sensor under the single output mode and the binning output mode according to some embodiments of the present disclosure. FIG. 19 is a schematic top view of the sensing unit in FIG. 17 and FIG. 18.

Referring to FIG. 1 to FIG. 4, an image sensor 1 according to some embodiments of the present disclosure is provided. The image sensor 1 may include a sensing unit 10. In some embodiments, although not shown, the image sensor 1 includes a plurality of sensing units 10 arranged in an array along a first direction D1 and a second direction D2 intersected with the first direction D1. The first direction D1 and the second direction D2 are perpendicular to a thickness direction (e.g., a third direction D3) of the image sensor 1. In some embodiments, as shown in FIG. 3, the first direction D1 is perpendicular to the second direction D2, but not limited thereto.

The sensing unit 10 includes a plurality of pixels P. For illustration purposes, as shown in the figures, a number of the plurality of pixels P in the sensing unit 10 is four, and the four pixels P are arranged into an array along the first direction D1 and the second direction D2, but not limited thereto. Each of the plurality of pixels P may include at least one photodiode PD, at least one first transistor (e.g., at least one first transfer gate transistor TX1) and a first source follower transistor SF1. In some embodiments, as shown in FIG. 3, in each of the plurality of pixels P of the sensing unit 10, a number of the at least one photodiode PD and the at least one first transistor (e.g., at least one first transfer gate transistor TX1) is plural, wherein the plurality of first transistors are electrically connected to the plurality of photodiodes PD and include a plurality of first transfer gate transistors TX1, but not limited thereto.

The sensing unit 10 may further include a plurality of second transistors (e.g., a plurality of second transfer gate transistor TX2) and a second source follower transistor SF2. In some embodiments, as shown in FIG. 3, the plurality of second transistors include a plurality of second transfer gate transistors TX2, and a total number of the plurality of second transfer gate transistors TX2 in the sensing unit 10 is less than or equal to a total number of the plurality of first transfer gate transistors TX1 in the sensing unit 10. For example, the total number of the plurality of second transfer gate transistor TX2 and the total number of the plurality of first transfer gate transistors TX1 in the sensing unit 10 is eight, but not limited thereto.

Specifically, if the number of the plurality of pixels P of the sensing unit 10 is N1, the number of the at least one photodiode PD in each of the plurality of pixels P of the sensing unit 10 is N2, the number of the at least one first transistor in each of the plurality of pixels P of the sensing unit 10 is N3, and the number of the plurality of second transistors is N4, then N1 to N4 are positive integers greater than 1, N2 is less than or equal to N1, N3 is larger than or equal to N2, and N4 is larger than or equal to N2. In FIG. 3, N1=4, N2=2, N3=2, and N4=8, but not limited thereto. For example, N2 may be equal to N1 or half of N1 (e.g., two or four), N3 may be equal to N2 or (N2+1) (e.g., two or three or four), N4 may be equal to (N1*N2), half of N1, N1, or half of (N1*N2) (e.g., two or four or eight).

In some embodiments, as shown in FIG. 3 and FIG. 4, the plurality of photodiodes PD are within a first substrate SUB1. The first substrate SUB1 may, for example, be or include a semiconductor material such as silicon, crystalline silicon, monocrystalline silicon, bulk silicon, epitaxial silicon, another semiconductor material, the like, or any combination of the foregoing.

The plurality of photodiodes PD within the first substrate SUB1 are spaced apart from each other. For example, the image sensor 1 may include an isolation structure ISO to separate and electrically isolate the plurality of photodiodes PD. The isolation structure ISO is disposed from a backside surface SB of the first substrate SUB1 to a point between the backside surface SB and a frontside surface SF of the first substrate SUB1, and the isolation structure ISO is disposed laterally between the plurality of photodiodes PD. In some embodiments, the isolation structure ISO may, for example, be configured as a back-side trench isolation (BTI) structure, a back-side deep trench isolation (BDTI) structure, another suitable isolation structure, or the like.

The plurality of photodiodes PD may be referred to as a plurality of photosensitive regions or a plurality of photodetectors. In some embodiments, the plurality of photodiodes PD are formed within the first substrate SUB1 through one or more selective ion implantation processes. In some embodiments, the plurality of photodiodes PD have a first conductivity type, and the first substrate SUB1 has a second conductivity type different from the first conductivity type. In some embodiments, the first conductivity type is n-type, and the second conductivity type is p-type, or vice versa.

In some embodiments, as shown in FIG. 3 and FIG. 4, the sensing unit 10 further includes a plurality of first floating diffusion regions FD1 within the first substrate SUB1 and electrically connected to the plurality of first source follower transistors SF1, wherein each of the plurality of first floating diffusion regions FD1 is shared between at least two corresponding first transistors (e.g., two first transfer gate transistors TX1) among the plurality of first transistors. The plurality of first floating diffusion regions FD1 are disposed adjacent to the frontside surface SF of the first substrate SUB1. In some embodiments, the conductivity type of the plurality of first floating diffusion regions FD1 may be the same as that of the plurality of photodiodes PD. In some embodiments, the plurality of first floating diffusion regions FD1 are serve as capacitors for storing the image charges.

In some embodiments, as shown in FIG. 3, the sensing unit 10 further includes at least one second floating diffusion region FD2 adjacent to the center of the sensing unit 10 and shared between the plurality of second transistors (e.g., the second transfer gate transistors TX2). In some embodiments, as shown in FIG. 3, a number of the at least one second floating diffusion region FD2 is two, and the two second floating diffusion regions FD2 are located on opposite sides of the center of the sensing unit 10. In addition, each of the two second floating diffusion regions FD2 is shared between four corresponding second transistors among the plurality of second transistors (e.g., the second transfer gate transistors TX2).

In some embodiments, as shown in FIG. 3 and FIG. 4, the plurality of first transistors (e.g., the first transfer gate transistors TX1) and the plurality of second transistors (e.g., a plurality of second transfer gate transistors TX2) are disposed on the first substrate SUB1 and electrically connected to the plurality of photodiodes PD. For example, the plurality of first transistors (e.g., the first transfer gate transistors TX1) and the plurality of second transistors (e.g., a plurality of second transfer gate transistor TX2) are disposed on the frontside surface SF of the first substrate SUB1. In some embodiments, the plurality of second transistors are closer to a center of the sensing unit 10 than the plurality of first transistors. In some embodiments, although not marked/shown, each of the transfer gate transistors (including the plurality of first transfer gate transistors TX1 and the plurality of second transfer gate transistors TX2) includes a gate structure and a sidewall spacer structure that laterally encloses the gate structure. In further embodiments, although not marked/shown, the gate structure includes a gate electrode overlying the substrate and a gate dielectric layer disposed between the substrate and the gate electrode.

In some embodiments, the plurality of first transistors and the plurality of second transistors (e.g., the plurality of first transfer gate transistors TX1 and the plurality of second transfer gate transistors TX2) are within a first interconnect structure ICT1 disposed on the frontside surface SF of the first substrate SUB1. In some embodiments, the first interconnect structure ICT1 includes an interconnect dielectric structure (not shown), a plurality of conductive wires within the interconnect dielectric structure, a plurality of conductive vias (not shown) within the interconnect dielectric structure and a plurality of contacts CT within the interconnect dielectric structure and connected to the plurality of first floating diffusion regions FD1.

In some embodiments, as shown in FIG. 3 and FIG. 4, the plurality of first source follower transistors SF1 and the second source follower transistor SF2 are disposed on a second substrate SUB2 overlapped with the first substrate SUB1. In some embodiments, the second source follower transistor SF2 is closer to the center of the sensing unit 10 than the plurality of first source follower transistors SF1. In some embodiments, the plurality of first source follower transistors SF1 and the second source follower transistor SF2 are within a second interconnect structure ICT2 on the second substrate SUB2. In some embodiments, although not shown, the second interconnect structure ICT2 includes an interconnect dielectric structure, a plurality of conductive wires within the interconnect dielectric structure and a plurality of conductive vias within the interconnect dielectric structure.

In some embodiments, as shown in FIG. 3 and FIG. 4, the first interconnect structure ICT1 is bonded and electrically connected to the second interconnect structure ICT2. For example, the first interconnect structure ICT1 and the second interconnect structure ICT2 may be bonded through a hybrid bond or a plurality of micro bumps, but not limited thereto. In these embodiments, the plurality of transistors (including the plurality of first transfer gate transistors TX1 and the plurality of second transfer gate transistors TX2) within the first interconnect structure ICT1 are located between the plurality of photodiodes PD and the plurality of source follower transistors (including the plurality of first source follower transistors SF1 and the second source follower transistor SF2) in a thickness direction (e.g., the third direction D3) of the image sensor 1.

In some embodiments, as shown in FIG. 3, the sensing unit 10 further includes a horizontal conductor HC and a plurality of vertical conductors VC. The horizontal conductor HC is extended between and electrically connected to the two second floating diffusion regions FD2. In some embodiments, the horizontal conductor HC includes at least one of the plurality of conductive wires within the interconnect dielectric structure of the first interconnect structure ICT1. At least one of the plurality of vertical conductors VC is extended between the horizontal conductor HC and the second source follower transistor SF2 and electrically connecting the horizontal conductor HC to the second source follower transistor SF2. The rest of the plurality of vertical conductors VC are extended between the plurality of first floating diffusion regions FD1 and the plurality of first source follower transistors SF1 and electrically connecting the plurality of first floating diffusion regions FD1 to the plurality of first source follower transistors SF1. In some embodiments, each of the plurality of vertical conductors VC includes a plurality of conductive vias stacked along the third direction D3 and within the interconnect dielectric structure of the first interconnect structure ICT1 and the interconnect dielectric structure of the second interconnect structure ICT2.

In some embodiments, as shown in FIG. 1 to FIG. 3, each of the plurality of pixels P further includes a first selection transistor (or row select transistor) SEL1, a first dual conversion gain transistor DCG1 and a first reset transistor RST1, and the sensing unit 10 further includes a second selection transistor (or row select transistor) SEL2, a second dual conversion gain transistor DCG2 and a second reset transistor RST2, but not limited thereto.

In some embodiments, as shown in FIG. 1 to FIG. 3, in each of the plurality of pixels P, the first source follower transistor SF1 is electrically connected to the first transfer gate transistors TX1 through the first floating diffusion region FD1 and electrically connected between the first selection transistor SEL1 and a DC voltage supply terminal VDD. The first selection transistor SEL1 is electrically connected between the first source follower transistor SF1 and an output Vout. The first dual conversion gain transistor DCG1 is electrically connected between the first floating diffusion region FD1 and the first reset transistor RST1. The first reset transistor RST1 is electrically connected between the first dual conversion gain transistor DCG1 and the DC voltage supply terminal VDD.

In the sensing unit 10, the second source follower transistor SF2 is electrically connected to the second transfer gate transistors TX2 through the second floating diffusion regions FD2 and electrically connected between the second selection transistor SEL2 and the DC voltage supply terminal VDD. The second selection transistor SEL2 is electrically connected between the second source follower transistor SF2 and an output Vout. The second dual conversion gain transistor DCG2 is electrically connected between the second floating diffusion regions FD2 and the second reset transistor RST2. The second reset transistor RST2 is electrically connected between the second dual conversion gain transistor DCG2 and the DC voltage supply terminal VDD.

The reset transistor (e.g., RST1, RST2) may be controlled by a reset signal provided to a gate of the reset transistor. Other control signals (e.g., a row select signal, a conversion gain signal and a transfer signal) may be likewise provided to respective gates of the selection transistor (e.g., SEL1, SEL2), dual conversion gain transistor (e.g., DCG1, DCG2) and transfer gate transistor (e.g., TX1, TX2). The various control signals may be provided by the control circuitry (not shown) to control the operation of the sensing unit 10 to enable its resetting and readout of a signal voltage therefrom, e.g., pixel data or image data output of the pixel.

In some embodiments, as shown in FIG. 3 and FIG. 4, the first selection transistors SEL1, the first dual conversion gain transistors DCG1, the first reset transistors RST1, the second selection transistor SEL2, the second dual conversion gain transistor DCG2 and the second reset transistor RST2 are disposed on the second substrate SUB2 and within the second interconnect structure ICT2.

In some embodiments, as shown in FIG. 3 and FIG. 4, the image sensor 1 further includes a grid structure GS disposed over the backside surface SB of the first substrate SUB1. The grid structure GS may include a plurality of openings A respectively overlapped with the plurality of pixels P. The grid structure GS may, for example, include a metal grid structure and/or a dielectric grid structure. A material of the metal grid structure may, for example, include aluminum, copper, tungsten, another material, or any combination of the foregoing. A material of the dielectric grid structure may, for example, include an oxide such as silicon dioxide, another dielectric material, or any combination of the foregoing.

In some embodiments, as shown in FIG. 4, the image sensor 1 further includes a plurality of color filters CF. The plurality of color filters CF are disposed over the backside surface SB of the first substrate SUB1. For example, the plurality of color filters CF are disposed in the plurality of openings A of the grid structure GS. The plurality of color filters CF may include a plurality of red color filters, a plurality of green color filters and a plurality of blue color filters, but not limited thereto. In some embodiments, the sensing unit 10 includes four pixels P of the same color, i.e., the color filters CF in the sensing unit 10 are of the same color.

In some embodiments, as shown in FIG. 3 and FIG. 4, the image sensor 1 further includes a plurality of micro-lenses ML. The plurality of micro-lenses ML may be disposed over the backside surface SB of the first substrate SUB1 and over the plurality of color filters CF. In some embodiments, the micro-lenses ML have a substantially flat bottom surface abutting the plurality of color filters CF and a curved upper surface. In certain embodiments, the curved upper surface is configured to focus an incident radiation or incident light. During operation of the image sensor 1, the incident radiation or incident light is focused by the micro-lens ML to the underlying photodiodes PD, where an electron-hole pair may be generated to produce a photocurrent.

In some embodiments, the center of the micro-lens ML and/or the center of the color filter CF may be shift with respect to the center of the underlying photodiodes PD to reduce the channel separation (i.e., the sensitivity difference between the subpixels/photodiodes under the same micro-lens) of QPD (Quad Photo Diode) or DPD (Dual Photo Diode).

Referring to FIG. 1 and FIG. 2, in each of the plurality of pixels P, the at least one photodiode PD is electrically connected to the first source follower transistor SF1 at least through the at least one first transistor (e.g., at least one first transfer gate transistor TX1), and electrically connected to the second source follower transistor SF2 at least through at least one corresponding second transistor (e.g., at least one second transfer gate transistor TX2) among the plurality of second transistors. For example, in each of the plurality of pixels P, the two photodiodes PD are electrically connected to the first source follower transistor SF1 through the two first transfer gate transistors TX1 and the first floating diffusion region FD1, and electrically connected to the second source follower transistor SF2 through the two second transfer gate transistors TX2 and the second floating diffusion regions FD2.

During operation of the image sensor 1 under a single output mode, as shown in FIG. 1, the first transfer gate transistors TX1 in the plurality of pixels P are sequentially turned on while the second transfer gate transistors TX2 in the plurality of pixels P are turned off. For example, in a first time interval, the first transfer gate transistors TX1 in a first pixel among the four pixels P are turned on and the first transfer gate transistors TX1 in the remaining three pixels among the four pixels P are turned off; in a second time interval, the first transfer gate transistors TX1 in a second pixel among the four pixels P are turned on and the first transfer gate transistors TX1 in the remaining three pixels among the four pixels P are turned off; and so on for the rest of the pixels.

During operation of the image sensor 1 under a single output mode, as shown in FIG. 1, the first transfer gate transistors TX1 controls charge transfer from the photodiodes PD to the first floating diffusion region FD1. If the charge level is sufficiently high within the first floating diffusion region FD1, the first source follower transistor SF1 is activated and a voltage proportional to the charge at the first floating diffusion region FD1 is output by the first selection transistor SEL1. In some embodiments, the first source follower transistor SF1 is able to provide high impedance output. For example, the first source follower transistor SF1 may be an amplifier transistor which amplifies the signal of the first floating diffusion region FD1 for readout operation. The first dual conversion gain transistor DCG1 is a transistor used to achieve a wide dynamic range with high and low conversion gains. The control signal provided to the gate of the first dual conversion gain transistor DCG1 may be varied depending on whether the high conversion gain or low conversion gain mode is desired. In the high conversion gain mode, the conversion gain signal drops to a low level, and the first dual conversion gain transistor DCG1 is turned off in response to the conversion gain signal. On the contrary, in the low conversion gain mode, the conversion gain signal is pulled up to a high level, and the first dual conversion gain transistor DCG1 is turned on in response to the conversion gain signal.

During operation of the image sensor 1 under a binning output mode, as shown in FIG. 2, the first transfer gate transistors TX1 in the plurality of pixels P are turned off while the second transfer gate transistors TX2 in the plurality of pixels P are turned on. The second transfer gate transistors TX2 controls charge transfer from the plurality of photodiodes PD to the second floating diffusion region FD2. If the charge level is sufficiently high within the second floating diffusion region FD2, the second source follower transistor SF2 is activated and a voltage proportional to the charge at the second floating diffusion region FD2 is output by the second selection transistor SEL2. In some embodiments, the second source follower transistor SF2 is able to provide high impedance output. For example, the second source follower transistor SF2 may be an amplifier transistor which amplifies the signal of the second floating diffusion region FD2 for readout operation. The second dual conversion gain transistor DCG2 is a transistor used to achieve a wide dynamic range with high and low conversion gains. The control signal provided to the gate of the second dual conversion gain transistor DCG2 may be varied depending on whether the high conversion gain or low conversion gain mode is desired. In the high conversion gain mode, the conversion gain signal drops to a low level, and the second dual conversion gain transistor DCG2 is turned off in response to the conversion gain signal. On the contrary, in the low conversion gain mode, the conversion gain signal is pulled up to a high level, and the second dual conversion gain transistor DCG2 is turned on in response to the conversion gain signal.

Since the single output mode and the binning output mode are executed by two pixel circuits, the metal routings corresponding to different modes can be reduced separately. In addition, the multiple transistors of the two pixel circuits are disposed on different levels, for example, the transfer gate transistors (e.g., TX1, TX2) of the two pixel circuits are disposed on the first substrate SUB1, while the other transistors (e.g., SF1, SF2, SEL1, SEL2, DCG1, DCG2, RST1, RST2) of the two pixel circuits are disposed on the second substrate SUB2. The floating diffusion regions (e.g., FD1, FD2) are within the first substrate SUB1, and the floating diffusion regions are electrically connected to the source follower transistors (e.g., SF1, SF2) through conductors (e.g., HC, VC). Therefore, the floating node routing and/or the parasitic capacitance caused by adjacent conductors on the same layer or different layers can be reduced, which helps to improve conversion gain, lower the read noise and/or improve the image quality.

Referring to FIG. 5 to FIG. 7, an image sensor 1A according to some embodiments of the present disclosure is provided. In FIG. 7, the second substrate and the transistors disposed on the second substrate are not shown, the relevant descriptions of the above components please refer to FIG. 3.

The image sensor 1A may include a sensing unit 10A. In some embodiments, although not shown, the image sensor 1A includes a plurality of sensing units 10A arranged in an array along the first direction D1 and the second direction D2. In each of the plurality of pixels P of the sensing unit 10A, the plurality of first transistors further include a first switch SW1 electrically connects the plurality of first transfer gate transistors TX1 to the first source follower transistor SF1. Specifically, the first switch SW1 electrically connects the first floating diffusion region FD1 to the first source follower transistor SF1 and the first dual conversion gain transistor DCG1. In addition, the plurality of second transistors include a plurality of second switches SW2 instead of a plurality of second transfer gate transistors. Each of the plurality of second switches SW2 electrically connects the plurality of first transfer gate transistors TX1 in a corresponding pixel P among the plurality of pixels P of the sensing unit 10A to the second source follower transistor SF2. Specifically, the plurality of second switches SW2 electrically connects the plurality of first floating diffusion regions FD1 to the second source follower transistor SF2 and the second dual conversion gain transistor DCG2.

Specifically, in the sensing unit 10A, each of the plurality of first floating diffusion regions FD1 is shared between three corresponding first transistors (e.g., two first transfer gate transistors TX1 and one first switch SW1) among the plurality of first transistors and one corresponding second transistor (e.g., one second switch SW2) among the plurality of second transistors. In addition, in the sensing unit 10A, each of the plurality of second transistors (the plurality of second switches SW2) is located between two corresponding first floating diffusion regions FD1 among the plurality of first floating diffusion regions FD1. Moreover, the horizontal conductor HC is extended between and electrically connected to the plurality of second transistors (the plurality of second switches SW2), at least one of the vertical conductors VC electrically connects the horizontal conductor HC to the second source follower transistor SF2 and the second dual conversion gain transistor DCG2, and the rest of the plurality of vertical conductors VC are extended between the plurality of first switch SW1 and the plurality of first source follower transistors SF1 and electrically connecting the plurality of first switch SW1 to the plurality of first source follower transistors SF1.

During operation of the image sensor 1A under a single output mode, as shown in FIG. 5, the plurality of first switch SW1 are turned on while the plurality of second switches SW2 are turned off. On the other hand, during operation of the image sensor 1A under a binning output mode, as shown in FIG. 6, the plurality of first switch SW1 are turned off while the plurality of second switches SW2 are turned on.

Referring to FIG. 8 to FIG. 10, an image sensor 1B according to some embodiments of the present disclosure is provided. In FIG. 10, the second substrate and the transistors disposed on the second substrate are not shown, the relevant descriptions of the above components please refer to FIG. 3.

The image sensor 1B may include a sensing unit 10B. In some embodiments, although not shown, the image sensor 1B includes a plurality of sensing units 10B arranged in an array along the first direction D1 and the second direction D2. The total number of the plurality of second transfer gate transistors TX2 in the sensing unit 10B is less than the total number of the plurality of first transfer gate transistors TX1 in the sensing unit 10B. For example, in the sensing unit 10B, the total number of the plurality of second transfer gate transistors TX2 is four, and the total number of the plurality of first transfer gate transistors TX1 is eight. In addition, the sensing unit 10B further includes a plurality of vertical transfer gate transistors VTG, wherein each of the plurality of vertical transfer gate transistors VTG is electrically connected between two corresponding photodiodes PD. Moreover, the plurality of photodiodes PD in each of the plurality of pixels P of the sensing unit 10B are electrically connected to the second source follower transistor SF2 at least through at least one corresponding second transfer gate transistor TX2 among the plurality of second transfer gate transistors TX2 and at least one corresponding vertical transfer gate transistor VTG among the plurality of vertical transfer gate transistors VTG.

Specifically, in the sensing unit 10B, a number of the at least one second floating diffusion region FD2 is one, and the second floating diffusion region FD2 is overlapped with the second source follower transistor SF2 (see FIG. 3) and shared between the plurality of second transistors (the plurality of second transfer gate transistors TX2). In addition, at least one of the vertical conductors VC is extended between the second floating diffusion region FD2 and the second source follower transistor SF2 and electrically connects the second floating diffusion region FD2 to the second source follower transistor SF2.

During operation of the image sensor 1B under a single output mode, as shown in FIG. 8, the first transfer gate transistors TX1 in the plurality of pixels P are sequentially turned on while the plurality of second transfer gate transistors TX2 and the plurality of vertical transfer gate transistors VTG in the sensing unit 10B are turned off. On the other hand, during operation of the image sensor 1B under a binning output mode, as shown in FIG. 9, the first transfer gate transistors TX1 in the plurality of pixels P are turned off while the plurality of second transfer gate transistors TX2 and the plurality of vertical transfer gate transistors VTG in the sensing unit 10B are turned on.

Referring to FIG. 11 to FIG. 13, an image sensor 1C according to some embodiments of the present disclosure is provided. In FIG. 13, the second substrate and the transistors disposed on the second substrate are not shown, the relevant descriptions of the above components please refer to FIG. 3.

The image sensor 1C may include a sensing unit 10C. In some embodiments, although not shown, the image sensor 1C includes a plurality of sensing units 10C arranged in an array along the first direction D1 and the second direction D2. The total number of the plurality of second transfer gate transistors TX2 in the sensing unit 10C is less than the total number of the plurality of first transfer gate transistors TX1 in the sensing unit 10C. For example, in the sensing unit 10C, the total number of the plurality of second transfer gate transistors TX2 is four, and the total number of the plurality of first transfer gate transistors TX1 is eight. In addition, in each of the plurality of pixels P of the sensing unit 10C, each of the plurality of second transfer gate transistors TX2 electrically connects the plurality of photodiodes PD in a corresponding pixel P among the plurality of pixels P of the sensing unit 10C to the second source follower transistor SF2.

Specifically, in each of the plurality of pixels P of the sensing unit 10C, as shown in FIG. 13, the number of the plurality of subpixels/photodiodes PD under the same micro-lens ML is two, the shape of each of the subpixels/photodiodes PD under the same micro-lens ML is a triangle, and the second transfer gate transistor TX2 overlaps the plurality of photodiodes PD.

During operation of the image sensor 1C under a single output mode, as shown in FIG. 11, the first transfer gate transistors TX1 in the plurality of pixels P are sequentially turned on while the plurality of second transfer gate transistors TX2 in the plurality of pixels P are turned off. On the other hand, during operation of the image sensor 1C under a binning output mode, as shown in FIG. 12, the first transfer gate transistors TX1 in the plurality of pixels P are turned off while the plurality of second transfer gate transistors TX2 in the plurality of pixels P are turned on.

Referring to FIG. 14 to FIG. 16, an image sensor 1D according to some embodiments of the present disclosure is provided. In FIG. 16, the second substrate and the transistors disposed on the second substrate are not shown, the relevant descriptions of the above components please refer to FIG. 3.

The image sensor 1D may include a sensing unit 10D. In some embodiments, although not shown, the image sensor 1D includes a plurality of sensing units 10D arranged in an array along the first direction D1 and the second direction D2. In each of the plurality of pixels P of the sensing unit 10D, the number of the plurality of photodiodes PD is four instead of two. In addition, in the sensing unit 10D, the total number of the plurality of second transfer gate transistors TX2 is eight, the total number of the plurality of first transfer gate transistors TX1 is sixteen, and the total number of the plurality of vertical transfer gate transistors VTG is eight. Moreover, the plurality of photodiodes PD in each of the plurality of pixels P of the sensing unit 10D are electrically connected to the second source follower transistor SF2 through two corresponding second transfer gate transistors TX2 among the plurality of second transfer gate transistors TX2, two corresponding vertical transfer gate transistors VTG among the plurality of vertical transfer gate transistors VTG, one of the plurality of second floating diffusion regions FD2, the horizontal conductor HC and at least one of the plurality of vertical conductors VC extended between the horizontal conductor HC and the second source follower transistor SF2.

During operation of the image sensor 1D under a single output mode, as shown in FIG. 14, the first transfer gate transistors TX1 in the plurality of pixels P are sequentially turned on while the plurality of second transfer gate transistors TX2 and the plurality of vertical transfer gate transistors VTG in the sensing unit 10D are turned off. On the other hand, during operation of the image sensor 1D under a binning output mode, as shown in FIG. 15, the first transfer gate transistors TX1 in the plurality of pixels P are turned off while the plurality of second transfer gate transistors TX2 and the plurality of vertical transfer gate transistors VTG in the sensing unit 10D are turned on.

Referring to FIG. 17 to FIG. 19, an image sensor 1E according to some embodiments of the present disclosure is provided. In FIG. 19, the second substrate and the transistors disposed on the second substrate are not shown, the relevant descriptions of the above components please refer to FIG. 3.

The image sensor 1E may include a sensing unit 10E. In some embodiments, although not shown, the image sensor 1E includes a plurality of sensing units 10E arranged in an array along the first direction D1 and the second direction D2. In each of the plurality of pixels P of the sensing unit 10E, the number of the plurality of photodiodes PD is four instead of two. In addition, in the sensing unit 10E, the total number of the plurality of second transfer gate transistors TX2 is four, the total number of the plurality of first transfer gate transistors TX1 is sixteen, and the total number of the plurality of vertical transfer gate transistors VTG is sixteen. Moreover, the plurality of photodiodes PD in each of the plurality of pixels P of the sensing unit 10E are electrically connected to the second source follower transistor SF2 through one corresponding second transfer gate transistors TX2 among the plurality of second transfer gate transistors TX2, four corresponding vertical transfer gate transistors VTG among the plurality of vertical transfer gate transistors VTG, the second floating diffusion region FD2 and at least one of the plurality of vertical conductors VC extended between the second floating diffusion region FD2 and the second source follower transistor SF2.

During operation of the image sensor 1E under a single output mode, as shown in FIG. 17, the first transfer gate transistors TX1 in the plurality of pixels P are sequentially turned on while the plurality of second transfer gate transistors TX2 and the plurality of vertical transfer gate transistors VTG in the sensing unit 10E are turned off. On the other hand, during operation of the image sensor 1E under a binning output mode, as shown in FIG. 18, the first transfer gate transistors TX1 in the plurality of pixels P are turned off while the plurality of second transfer gate transistors TX2 and the plurality of vertical transfer gate transistors VTG in the sensing unit 10E are turned on.

Based on the above discussions, it can be seen that the present disclosure offers various advantages. It is understood, however, that not all advantages are necessarily discussed herein, and other embodiments may offer different advantages, and that no particular advantage is required for all embodiments.

According to some embodiments, an image sensor includes a sensing unit. The sensing unit includes a plurality of pixels. Each of the plurality of pixels includes at least one photodiode, at least one first transistor and a first source follower transistor. The sensing unit further includes a plurality of second transistors and a second source follower transistor. In each of the plurality of pixels, the at least one photodiode is electrically connected to the first source follower transistor at least through the at least one first transistor, and electrically connected to the second source follower transistor at least through at least one corresponding second transistor among the plurality of second transistors.

In some embodiments, a number of the plurality of pixels of the sensing unit is N1. In each of the plurality of pixels of the sensing unit, a number of the at least one photodiode is N2, and a number of the at least one first transistor is N3. A number of the plurality of second transistors is N4. N1 to N4 are positive integers greater than 1, N2 is less than or equal to N1, N3 is larger than or equal to N2, and N4 is larger than or equal to N2.

In some embodiments, in each of the plurality of pixels of the sensing unit, a number of the at least one photodiode and the at least one first transistor is plural, and the plurality of first transistors are electrically connected to the plurality of photodiodes. The plurality of first transistors include a plurality of first transfer gate transistors.

In some embodiments, the plurality of second transistors include a plurality of second transfer gate transistors, and a total number of the plurality of second transfer gate transistors in the sensing unit is less than or equal to a total number of the plurality of first transfer gate transistors in the sensing unit.

In some embodiments, the total number of the plurality of second transfer gate transistors in the sensing unit is less than the total number of the plurality of first transfer gate transistors in the sensing unit. The sensing unit further includes a plurality of vertical transfer gate transistors, wherein each of the plurality of vertical transfer gate transistors is electrically connected between two corresponding photodiodes. The plurality of photodiodes in each of the plurality of pixels of the sensing unit are electrically connected to the second source follower transistor at least through at least one corresponding second transfer gate transistor among the plurality of second transfer gate transistors and at least one corresponding vertical transfer gate transistor among the plurality of vertical transfer gate transistors.

In some embodiments, the total number of the plurality of second transfer gate transistors in the sensing unit is less than the total number of the plurality of first transfer gate transistors in the sensing unit. Each of the plurality of second transfer gate transistors electrically connects the plurality of photodiodes in a corresponding pixel among the plurality of pixels of the sensing unit to the second source follower transistor.

In some embodiments, in each of the plurality of pixels of the sensing unit, the plurality of first transistors further include a first switch electrically connects the plurality of first transfer gate transistors to the first source follower transistor. The plurality of second transistors include a plurality of second switches. Each of the plurality of second switches electrically connects the plurality of first transfer gate transistors in a corresponding pixel among the plurality of pixels of the sensing unit to the second source follower transistor.

According to some embodiments, an image sensor includes a sensing unit. The sensing unit includes a plurality of photodiodes, a plurality of transistors electrically connected to the plurality of photodiodes and a plurality of source follower transistors. The plurality of transistors are located between the plurality of photodiodes and the plurality of source follower transistors in a thickness direction of the image sensor. The plurality of photodiodes are electrically connected to a plurality of first source follower transistors among the plurality of source follower transistors through a plurality of first transistors among the plurality of transistors, and electrically connected to a second source follower transistor among the plurality of source follower transistors through a plurality of second transistors among the plurality of transistors. The plurality of second transistors are closer to a center of the sensing unit than the plurality of first transistors. The second source follower transistor is closer to the center of the sensing unit than the plurality of first source follower transistors.

In some embodiments, the sensing unit further includes a plurality of first floating diffusion regions overlapped with and electrically connected to the plurality of first source follower transistors, wherein each of the plurality of first floating diffusion regions is shared between at least two corresponding first transistors among the plurality of first transistors.

In some embodiments, the sensing unit further includes a plurality of vertical conductors extended between the plurality of first floating diffusion regions and the plurality of first source follower transistors and electrically connecting the plurality of first floating diffusion regions to the plurality of first source follower transistors.

In some embodiments, the sensing unit further includes at least one second floating diffusion region adjacent to the center of the sensing unit and shared between the plurality of second transistors.

In some embodiments, in the sensing unit, a number of the at least one second floating diffusion region is two, the two second floating diffusion regions are located on opposite sides of the center of the sensing unit, and each of the two second floating diffusion regions is shared between four corresponding second transistors among the plurality of second transistors. The sensing unit further includes a horizontal conductor and a vertical conductor. The horizontal conductor is extended between and electrically connected to the two second floating diffusion regions. The vertical conductor is extended between the horizontal conductor and the second source follower transistor and electrically connects the horizontal conductor to the second source follower transistor.

In some embodiments, in the sensing unit, a number of the at least one second floating diffusion region is one, the second floating diffusion region is overlapped with the second source follower transistor and shared between the plurality of second transistors, and the sensing unit further includes a vertical conductor extended between the second floating diffusion region and the second source follower transistor and electrically connecting the second floating diffusion region to the second source follower transistor.

In some embodiments, the sensing unit further includes a plurality of vertical transfer gate transistors, wherein each of the plurality of vertical transfer gate transistors is electrically connected between two corresponding photodiodes.

In some embodiments, in the sensing unit, each of the plurality of first floating diffusion regions is shared between three corresponding first transistors among the plurality of first transistors and one corresponding second transistor among the plurality of second transistors, and each of the plurality of second transistors is located between two corresponding first floating diffusion regions among the plurality of first floating diffusion regions. The sensing unit further includes a horizontal conductor and a vertical conductor. The horizontal conductor is extended between and electrically connected to the plurality of second transistors. The vertical conductor is extended between the horizontal conductor and the second source follower transistor and electrically connects the horizontal conductor to the second source follower transistor.

According to some embodiments, an image sensor includes a sensing unit. The sensing unit includes a plurality of photodiodes within a first substrate, a plurality of first transistors disposed on the first substrate and electrically connected to the plurality of photodiodes, a plurality of second transistors disposed on the first substrate and electrically connected to the plurality of photodiodes, a plurality of first source follower transistors disposed on a second substrate overlapped with the first substrate and a second source follower transistor disposed on the second substrate. The plurality of photodiodes are electrically connected to the plurality of first source follower transistors through the plurality of first transistors, and electrically connected to the second source follower transistor through the plurality of second transistors.

In some embodiments, in the sensing unit, the plurality of first transistors and the plurality of second transistors are within a first interconnect structure on the first substrate, the plurality of first source follower transistors and the second source follower transistor are within a second interconnect structure on the second substrate, and the first interconnect structure is bonded and electrically connected to the second interconnect structure.

In some embodiments, the sensing unit includes four pixels of the same color.

In some embodiments, the sensing unit further includes a plurality of first floating diffusion regions within the first substrate and electrically connected to the plurality of first source follower transistors, wherein each of the plurality of first floating diffusion regions is shared between at least two corresponding first transistors among the plurality of first transistors.

In some embodiments, the sensing unit further includes at least one second floating diffusion region within the first substrate and adjacent to the center of the sensing unit and shared between the plurality of second transistors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
a sensing unit comprising:
a plurality of pixels, wherein each of the plurality of pixels comprises at least one photodiode, at least one first transistor and a first source follower transistor;
a plurality of second transistors; and
a second source follower transistor,
wherein in each of the plurality of pixels, the at least one photodiode is electrically connected to the first source follower transistor at least through the at least one first transistor, and electrically connected to the second source follower transistor at least through at least one corresponding second transistor among the plurality of second transistors.

2. The image sensor as claimed in claim 1, wherein:
a number of the plurality of pixels of the sensing unit is N1,
in each of the plurality of pixels of the sensing unit, a number of the at least one photodiode is N2, and a number of the at least one first transistor is N3,
a number of the plurality of second transistors is N4,
N1 to N4 are positive integers greater than 1,
N2 is less than or equal to N1,
N3 is larger than or equal to N2, and
N4 is larger than or equal to N2.

3. The image sensor as claimed in claim 1, wherein:
in each of the plurality of pixels of the sensing unit, a number of the at least one photodiode and the at least one first transistor is plural, and the plurality of first transistors are electrically connected to the plurality of photodiodes, and
the plurality of first transistors comprise a plurality of first transfer gate transistors.

4. The image sensor as claimed in claim 3, wherein the plurality of second transistors comprise a plurality of second transfer gate transistors, and a total number of the plurality of second transfer gate transistors in the sensing unit is less than or equal to a total number of the plurality of first transfer gate transistors in the sensing unit.

5. The image sensor as claimed in claim 4, wherein:
the total number of the plurality of second transfer gate transistors in the sensing unit is less than the total number of the plurality of first transfer gate transistors in the sensing unit,
the sensing unit further comprises a plurality of vertical transfer gate transistors, wherein each of the plurality of vertical transfer gate transistors is electrically connected between two corresponding photodiodes, and
wherein the plurality of photodiodes in each of the plurality of pixels of the sensing unit are electrically connected to the second source follower transistor at least through at least one corresponding second transfer gate transistor among the plurality of second transfer gate transistors and at least one corresponding vertical transfer gate transistor among the plurality of vertical transfer gate transistors.

6. The image sensor as claimed in claim 4, wherein:
the total number of the plurality of second transfer gate transistors in the sensing unit is less than the total number of the plurality of first transfer gate transistors in the sensing unit, and
each of the plurality of second transfer gate transistors electrically connects the plurality of photodiodes in a corresponding pixel among the plurality of pixels of the sensing unit to the second source follower transistor.

7. The image sensor as claimed in claim 3, wherein:
in each of the plurality of pixels of the sensing unit, the plurality of first transistors further comprise a first switch electrically connects the plurality of first transfer gate transistors to the first source follower transistor,
the plurality of second transistors comprise a plurality of second switches, and
each of the plurality of second switches electrically connects the plurality of first transfer gate transistors in a corresponding pixel among the plurality of pixels of the sensing unit to the second source follower transistor.

8. An image sensor, comprising:
a sensing unit comprising:
a plurality of photodiodes;
a plurality of transistors electrically connected to the plurality of photodiodes; and
a plurality of source follower transistors, wherein:
the plurality of transistors are located between the plurality of photodiodes and the plurality of source follower transistors in a thickness direction of the image sensor,
the plurality of photodiodes are electrically connected to a plurality of first source follower transistors among the plurality of source follower transistors through a plurality of first transistors among the plurality of transistors, and electrically connected to a second source follower transistor among the plurality of source follower transistors through a plurality of second transistors among the plurality of transistors,
the plurality of second transistors are closer to a center of the sensing unit than the plurality of first transistors, and
the second source follower transistor is closer to the center of the sensing unit than the plurality of first source follower transistors.

9. The image sensor as claimed in claim 8, wherein the sensing unit further comprises:
a plurality of first floating diffusion regions overlapped with and electrically connected to the plurality of first source follower transistors, wherein each of the plurality of first floating diffusion regions is shared between at least two corresponding first transistors among the plurality of first transistors.

10. The image sensor as claimed in claim 9, wherein the sensing unit further comprises:
a plurality of vertical conductors extended between the plurality of first floating diffusion regions and the plurality of first source follower transistors and electrically connecting the plurality of first floating diffusion regions to the plurality of first source follower transistors.

11. The image sensor as claimed in claim 9, wherein the sensing unit further comprises:
at least one second floating diffusion region adjacent to the center of the sensing unit and shared between the plurality of second transistors.

12. The image sensor as claimed in claim 11, wherein in the sensing unit:
a number of the at least one second floating diffusion region is two,
the two second floating diffusion regions are located on opposite sides of the center of the sensing unit,
each of the two second floating diffusion regions is shared between four corresponding second transistors among the plurality of second transistors, and
the sensing unit further comprises:
a horizontal conductor extended between and electrically connected to the two second floating diffusion regions; and
a vertical conductor extended between the horizontal conductor and the second source follower transistor and electrically connecting the horizontal conductor to the second source follower transistor.

13. The image sensor as claimed in claim 11, wherein in the sensing unit:
a number of the at least one second floating diffusion region is one,
the second floating diffusion region is overlapped with the second source follower transistor and shared between the plurality of second transistors, and
the sensing unit further comprises a vertical conductor extended between the second floating diffusion region and the second source follower transistor and electrically connecting the second floating diffusion region to the second source follower transistor.

14. The image sensor as claimed in claim 11, wherein the sensing unit further comprises a plurality of vertical transfer gate transistors, wherein each of the plurality of vertical transfer gate transistors is electrically connected between two corresponding photodiodes.

15. The image sensor as claimed in claim 9, wherein in the sensing unit:
each of the plurality of first floating diffusion regions is shared between three corresponding first transistors among the plurality of first transistors and one corresponding second transistor among the plurality of second transistors,
each of the plurality of second transistors is located between two corresponding first floating diffusion regions among the plurality of first floating diffusion regions, and
the sensing unit further comprises:
a horizontal conductor extended between and electrically connected to the plurality of second transistors; and
a vertical conductor extended between the horizontal conductor and the second source follower transistor and electrically connecting the horizontal conductor to the second source follower transistor.

16. An image sensor, comprising:
a sensing unit comprising:
a plurality of photodiodes within a first substrate;
a plurality of first transistors disposed on the first substrate and electrically connected to the plurality of photodiodes;
a plurality of second transistors disposed on the first substrate and electrically connected to the plurality of photodiodes;
a plurality of first source follower transistors disposed on a second substrate overlapped with the first substrate; and
a second source follower transistor disposed on the second substrate, wherein the plurality of photodiodes are electrically connected to the plurality of first source follower transistors through the plurality of first transistors, and electrically connected to the second source follower transistor through the plurality of second transistors.

17. The image sensor as claimed in claim 16, wherein in the sensing unit:
the plurality of first transistors and the plurality of second transistors are within a first interconnect structure on the first substrate,
the plurality of first source follower transistors and the second source follower transistor are within a second interconnect structure on the second substrate, and
the first interconnect structure is bonded and electrically connected to the second interconnect structure.

18. The image sensor as claimed in claim 16, wherein the sensing unit comprises four pixels of the same color.

19. The image sensor as claimed in claim 16, wherein the sensing unit further comprises:
a plurality of first floating diffusion regions within the first substrate and electrically connected to the plurality of first source follower transistors, wherein each of the plurality of first floating diffusion regions is shared between at least two corresponding first transistors among the plurality of first transistors.

20. The image sensor as claimed in claim 19, wherein the sensing unit further comprises:
at least one second floating diffusion region within the first substrate and adjacent to the center of the sensing unit and shared between the plurality of second transistors.
